(19) United States
(12) Patent Application Publication
(10) Pub. No.: US 2005/0218967 A1
(43) Pub. Date: Oct. 6, 2005

(54) Reference circuitry and method of operating the same

(75) Inventor: Tahir Rashid, Maidenhead (GB)

Correspondence Address: Docket Clerk, P.O. Box 802432, Dallas, TX, 75380, US

(73) Assignee: STMicroelectronics Limited, Marlow (GB)

(21) Appl. No.: 10/962,371

(22) Filed: Oct. 9, 2004

(30) Foreign Application Priority Data
Oct. 9, 2003 (EP) 03256354.6

(51) Int. Cl. H03K 3/42

(52) U.S. Cl. 327/540

(57) ABSTRACT

A circuit for maintaining a generated reference voltage at a substantially constant level for a range of temperatures. The circuitry comprising: a first circuit arranged to generate a first voltage having a first temperature characteristic, and a second circuit arranged to generate a second voltage having a second temperature characteristic. The second voltage compensates for the first voltage to maintain the reference voltage at a substantially constant level over a first temperature range. The circuit also having a third circuit arranged to act in a second temperature range to compensate for the first voltage to maintain the reference voltage at a substantially constant level in the second temperature range.

### FIELD OF THE INVENTION

The present invention relates to integrated circuitry and in particular, but not exclusively, to generating a reference voltage.

### BACKGROUND OF THE INVENTION

Bandgap reference circuits form an important part of many electronic systems. These circuits provide a reference voltage that should preferably remain constant in all conditions, and particularly in the face of varying temperatures. The simplest bandgap references are created by compensating for the deviation of the base-emitter voltage (V_{be}) of a bipolar transistor with respect to temperature, by using a PTAT generator which generates a voltage proportional to absolute temperature (V_{PTAT}).

FIG. 1 shows a PRIOR ART PTAT generator. The circuit in FIG. 1 has first and second branches 100, 200, each being connected between a supply voltage VDD and a ground voltage GND. The first branch 100 comprises an emitter resistance Re1, a first bipolar transistor Q1 with its base tied to its collector, a second bipolar transistor Q3 and a resistor R. The resistor R is connected to ground at one end and to the emitter of the second transistor Q3. The collector of the second transistor is connected to the collector of the first transistor Q1. The emitter of the first transistor Q1 is connected to one end of the emitter resistor Re1 and the other end of the emitter resistor is connected to the supply voltage VDD.

The second branch 200 includes a third bipolar transistor Q2 with its base connected to the base of the first bipolar transistor Q1 in the first branch in a current mirror configuration, and a fourth bipolar transistors Q4 with its base connected to its collector and its base also connected to the base of the second bipolar transistor Q3 in the first branch in a current mirror configuration. The emitter of the fourth transistor Q4 is connected to ground and the collector of the fourth transistor is connected to the collector of the third transistor Q2. Also the emitter of the third transistor Q2 is connected to one end of a second emitter resistor Re2 and the other end of the second emitter resistor is connected to the supply voltage VDD.

It can be seen that the first and third transistors (Q1, Q2) are connected in a current mirror configuration, as are the second and fourth transistors (Q3, Q4). The current mirrors are used to reflect the changes in current in the first branch. 100 into the second branch 200.

In this circuit assuming that the area of the second bipolar transistor Q3 is n times the area of the fourth bipolar transistor Q4, it can be shown that the current generated in the first branch 100 (I_{PTAT}) shown in FIG. 1 is given by:

$${I}_{PTAT} = \frac{{V}_{P} ln ( n )}{R}$$

where V_{P} is the thermal voltage

$$( \frac{KT}{q} )$$

and ln(n) is the natural logarithm of n. Hence I_{PTAT} is proportional to the absolute temperature T.

The PTAT circuitry described in FIG. 1 typically generates a voltage with a positive temperature coefficient and is generally used as is shown in FIG. 2 to compensate for the negative temperature coefficient of a base-emitter voltage of a bipolar transistor. That is FIG. 2 shows a graph of voltage versus temperature, wherein three curves 20, 22 and 24 are shown. The first curve 20 shows the negative coefficient of the base emitter voltage of a bipolar transistor (V_{be}), wherein the voltage decreases as the temperature increases in a non-linear fashion. Note this is exaggerated and the shape is not accurate. The second curve 22 is indicative of the positive temperature coefficient of a PTAT voltage as shown in FIG. 1, wherein as temperature increases so does voltage in a linear fashion. The third curve 24 shows a so-called “first order” approximation of the summation of the first and second curves 20, 22 and represents the generated reference voltage V_{ref}. The aim of the PTAT generator is to compensate for the voltage variation with temperature of bipolar transistors, so that the output voltage V_{ref} is maintained at a substantially constant level. It is called a first order bandgap because the PTAT compensates the V_{be} behaviour with respect to temperature to the first order, i.e. linear part only. As a matter of practice however the result of summing curves 20 and 22 is a substantially “bell-shaped” curve as shown by the third curve 24. The bell shape arises from the higher terms of the V_{be} in temperature that are not compensated for. This is primarily in the form of TlnT, where T is the temperature.

The designer of the PTAT circuit is able to design a particular bell-shape by scaling the components of the PTAT generator accordingly. However, as can be seen from FIG. 2, each bell curve will have a reasonably “flat” or linear region, in which the generated reference voltage remains relatively constant over a certain temperature range defined by T1 and T2 on the temperature axis. The curve shows that outside the temperatures T1 and T2 the effect of the second order effects becomes increased, which means that changes to the temperatures outside of the temperature range defined by T1 and T2 will have a far greater impact on the generated reference voltage V_{ref}.

The bell-shape can be determined by the gradient of VPTAT, and the PTAT generator will normally be scaled so as to maximise the “flattish” region of the bell-shape. This already provides some improvement in temperature dependent behaviour.

### SUMMARY OF THE INVENTION

To address the above-discussed deficiencies of the prior art, it is a primary object of an embodiment of the present invention to generate reference signals and offer improved temperature compensation over a greater range of temperatures.

According to one aspect of the present invention there is provided a reference generating circuitry for generating a reference signal, the circuitry comprising: a first circuit arranged to generate a first signal having a first, non-linear temperature characteristic; a second circuit arranged- to generate a second signal having a second, linear temperature characteristic and which partially compensates for the first signal in a first temperature range and a third circuit arranged to generate a third signal with a third, non-linear, temperature characteristic which acts to compensate for the first signal in a second temperature range.

According to another aspect of the present invention there is provided a method for generating a reference signal, the method comprising: generating a first signal having a first, non-linear, temperature characteristic; generating a second signal having a second linear temperature characteristic which acts to compensate partially for the first signal in a first temperature range; and generating a third signal with a third, non-linear characteristic which acts to compensate for the first signal in a second temperature range.

According to a further aspect of the present invention there is provided a reference generating circuitry for generating a reference signal, the circuitry comprising: a first circuit arranged to generate a first signal having a first non-linear temperature characteristic; a second circuit arranged to generate a second signal having a second substantially linear temperature characteristic and which partially compensates for the first signal according to a compensation characteristic; and a third circuit arranged to modify the compensation characteristic of the first signal in a non-linear fashion.

According to a further aspect of the present invention there is provided a method for generating a reference signal, the method comprising: generating a first signal having a first, non-linear, temperature characteristic; generating a second signal having a second, substantially linear, temperature characteristic which acts to compensate partially for the first signal according to a compensation characteristic; and modifying the compensation characteristic for the first signal in a non-linear fashion.

In the embodiment described herein, the compensation characteristic is a bell curve. It is “flattened” when modified to provide a more stable response over a larger temperature range.

For a better understanding of the present invention and to show how the same may be carried into effect, reference will now be made by way of example to the accompanying drawings.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; and the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

Other features and advantages of the invention will become apparent in the following description of non limiting exemplary embodiments, with reference to the accompanying drawings, in which like reference numerals represent like parts, and in which:

FIG. 1 shows a PTAT bias circuit known in the prior art;

FIG. 2 shows voltage versus temperature curves;

FIG. 3 shows voltage versus temperature curves in accordance with an embodiment of the present invention;

FIG. 4 shows a bandgap reference circuit which accounts for temperature variations according to an embodiment of the present invention; and

FIG. 5 shows some simulation results illustrating the performance of the circuit of FIG. 4.

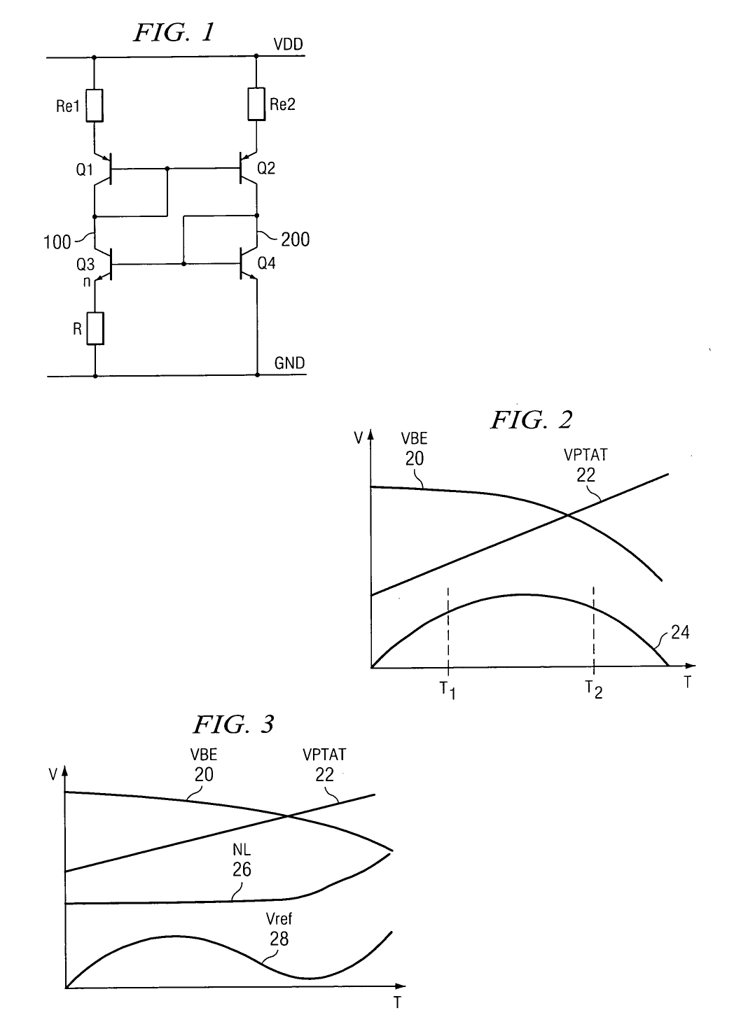

### DETAILED DESCRIPTION OF THE INVENTION

FIGS. 3 through 5, discussed below, and the various embodiments used to describe the principles of the present invention in this patent document are by way of illustration only and should not be construed in any way to limit the scope of the invention. Those skilled in the art will understand that the principles of the present invention may be implemented in any suitably arranged circuit for maintaining a generated reference voltage at a substantially constant level for a range of temperatures.

FIG. 3 shows a plurality of voltage versus temperature curves for the purposes of explaining the function of a preferred embodiment of the present invention. As explained before, the V_{PTAT} curve 22′ is shown as being substantially linear in that voltage changes are directly proportional to temperature changes, whereas in contrast the V_{be} curve 20′ is non-linear. Curves 20′ and 22′ equivalent to curves 20 and 22 in FIG. 2.

A non-linear compensation curve 26 illustrates the effect of a non-linear component which has been introduced into the circuit, and which has a flat response for temperatures in a first temperature range, but exhibits a positive non-linear (NL) voltage gradient for temperatures in a second temperature range. The NL characteristic of the fourth curve 26 can be achieved by a NL component into the first order bandgap reference circuit so as to provide an improved reference voltage.

The non-linear component serves two purposes as can be seen from FIG. 3. Firstly, it is able to compensate for the NL behaviour of the base-emitter voltage of the bipolar transistor at high temperatures, and secondly it allows the designer of the PTAT generator to scale the generator to generate a V_{PTAT} gradient which can be more closely tailored to compensate for the Vbe at temperatures in the first temperature range. It is easier to achieve a flat response from the bell shape in the first temperature range because temperatures in the second temperature range are already compensated for by the NL component.

Voltage variation described in relation to the generated reference voltage V_{ref} is often quoted in parts per million by degrees centigrade (ppm/° C.).

FIG. 3 also shows the reference voltage V_{ref} curve 28 which is now produced as a result of the first, second, and non-linear curves 20, 22, 26. The curve 28 shows an improvement over the prior art bandgap reference voltage in that at high temperatures the non-linear component is enabled. Also, for temperatures in the first temperature range the PTAT generator is scaled so that the bell-shaped curve can be flattened to reduce voltage variations in this temperature range.

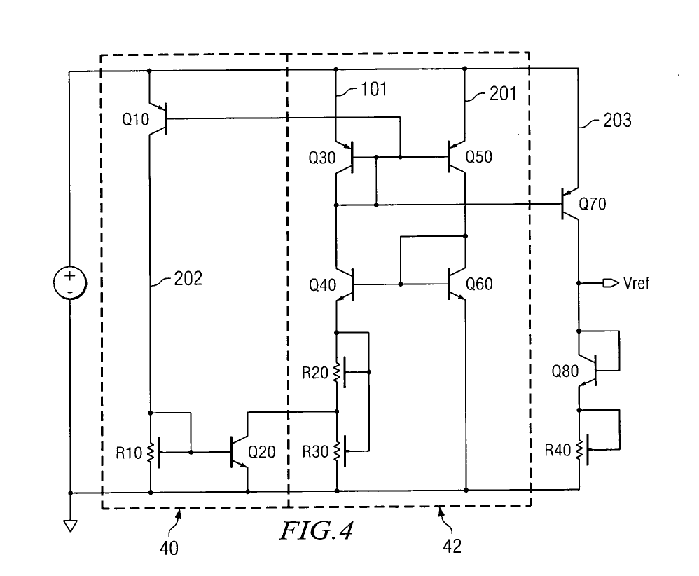

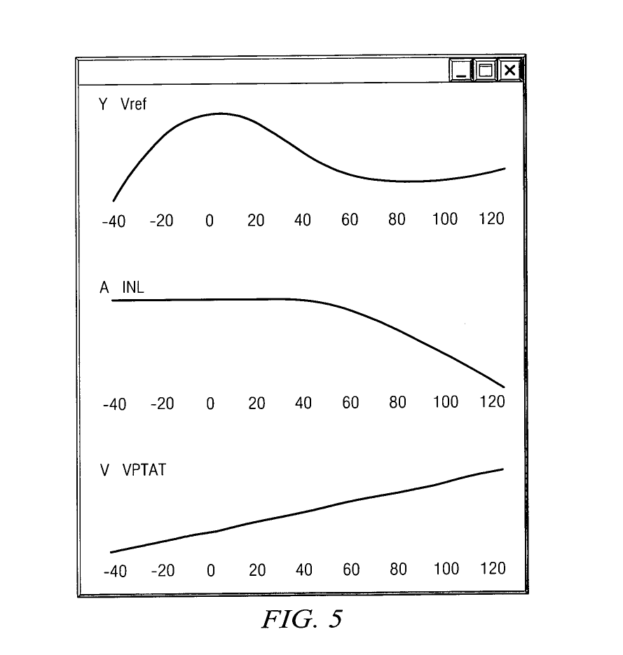

FIG. 4 shows a preferred embodiment of a circuit used for implementing the present invention. In particular, FIG. 4 shows circuitry 40, which is responsible for producing the non-linear component that is used to affect the reference voltage so that it is maintained at a substantially constant level even at higher temperatures. It should be appreciated that FIG. 4 is a highly simplified embodiment and that other alternatives may also be used. In particular, the circuit of FIG. 4 does not show a start-up circuit which could be added. Also the circuitry 40 is shown as comprising a first and a second bipolar transistor (Q10, Q20) and a resistor R10. However, it should be appreciated that other circuit configurations could be used, which allow a non-linear component to be introduced to compensate for the affects of temperature variations on the reference voltage V_{ref}.

The circuitry of FIG. 4 will now be described. The circuitry 40 which is responsible for producing the non-linear element comprises a first branch 202 having a first transistor Q10 whose emitter is connected to a supply voltage VDD and whose collector is connected to one end of a resistor R10. The other end of resistor R10 is connected to ground GND. Also, the collector of transistor Q10 is connected to the base of a second transistor Q20 and is also connected to a control terminal of resistor R10 to control the resistance setting of R10.

A PTAT circuit 42 is formed by the transistors Q30, Q40, Q50, Q60 and by the resistors R20 and R30. In particular, a first branch 101 comprises the transistor Q30 having its emitter connected to the supply voltage VDD and its collector connected to the transistor Q40. The emitter of transistor Q40 is connected to one end of a resistor R20 and the other end of the resistor R20 is connected to a further resistor R30 as well as the collector terminal of the transistor Q20 (which forms part of the non-linear circuit 40).

A second branch 201 of the PTAT circuit 42 comprises a transistor Q50 having an emitter connected to the supply voltage VDD and a collector connected to a collector of a transistor Q60. The emitter of transistor Q60 being connected to ground GND.

Furthermore, the collector of transistor Q30 is connected to the base of transistor Q30 which is also connected to the base of transistor Q50 so that a first current mirror is formed. Also, the collector of transistor Q50 is connected to its base which is also connected to the base of transistor Q40, thereby forming a second current mirror from transistors Q40 and Q60.

A further connection is provided between the base of transistor Q10 in the non-linear circuit 40 and the common base of transistors Q30 and Q50. This connection allows the introduction of the non-linear component into the current I_{PTAT} generated by the PTAT generator to compensate for temperature fluctuations (as will be explained later). That is, the generated current I_{PTAT} is reflected in a further branch 203 using a third current mirror formed by the transistors Q30 and Q70.

Transistor Q70 has its emitter terminal connected to the supply voltage VDD and its base terminal connected to the common base terminals of transistors Q10, Q30 and Q50. Thus, the generated PTAT current (I_{PTAT}) is mirrored into the third branch 203 using transistor Q70. The collector of transistor Q70 of branch 203 is connected to the collector and base terminals of transistor Q80. The emitter of transistor Q80 is connected to a resistor R40 at one end and the other end of R40 being connected to ground GND.

The transistor Q80 has a negative temperature coefficient that is non-linear. That is, in the preferred embodiment shown in FIG. 4 the transistor circuitry is a bipolar transistor having a non-linear negative temperature coefficient, which affects the voltage across its base-emitter junction (Vbe). Moreover, the reference voltage (Vref) generated by the bandgap reference circuit is determined at the collector of transistor Q70 as being the voltage drop across the base-emitter junction of transistor Q80 and the voltage drop across the resistor R40. The voltage drop across resistor R40 is determined by the current I_{PTAT} generated by the PTAT circuitry 42 which is mirrored into the branch 203 using transistor Q70.

V_{ref} is compensated using the equation:
V_{ref}=Vbe(Q80)+I_{PTAT}×R40
where I_{PTAT} is the current generated by the PTAT circuitry 42, which is also effected by the non-linear component generated by the non-linear circuitry 42 at high temperatures.

The operation of the circuit shown in the embodiment of FIG. 4 is fairly simple in that the transistors Q10 and Q20 and the resistor R10 form the NL compensation circuit 40, and the transistor Q10 forms a fourth current mirror with the transistor Q30 in the PTAT circuitry 42 so that the PTAT current I_{PTAT} generated by the PTAT generator 42 in branch 101 is mirrored into branch 202 of the NL compensation circuitry 40 and driven through resistor R10. Transistor Q10 and resistor R10 in the non-linear compensation circuit 40 are scaled such that at temperatures in the first temperature range the voltage across R10 is low enough to prevent the transistor Q20 from turning on. As such the non-linear compensation circuit 40 will have no effect on the bandgap reference at temperatures in the first temperature range, which is in line with the curves shown in FIG. 3. In particular, the non-linear curve 26 is shown as having a constant voltage between lower and higher voltages (i.e. between zero and the line AA) and will not have any effect on the reference voltage V_{ref}. Instead the bell-shaped curve can be shaped to have a flatter region extending over the first temperature range by scaling the PTAT generator 42.

However, if one considers the circuit of FIG. 4 to move into higher temperatures, then the PTAT current I_{PTAT} continues to increase until it reaches a point where the voltage across resistor R10 is sufficiently large to turn on transistor Q20. At this point the PTAT current I_{PTAT} flowing through the branch 101 is increased even further since the resistance through this branch is decreased. By turning the transistor Q20 fully on, the resistor R30 is effectively removed from the circuit, since current flows through the lower resistance switching terminals of Q20 to ground. However by controlling the degree to which transistor Q20 is turned on (i.e. by controlling the magnitude of the voltage generated across R1), it is possible to determine the magnitude of the respective currents which split between the resistor R30 and the switching terminals of transistors Q20 when turned on. That is, how fully the transistor Q20 is turned on will determine how much current will actually still flow through the resistor R30. However, in any event it will be appreciated that by scaling the resistors R20 and R30 one can control the magnitude of the increase in current generated by the PTAT circuitry I_{PTAT}.

The generated current I_{PTAT} is reflected using the transistor Q70 into the branch 203. At high temperatures the current will be affected by the non-linear component provided by the non-linear compensation circuit 40. The current generated by the PTAT circuitry I_{PTAT} will then flow through the resistor R40 which in turn will set up a voltage drop V_{PTAT} across the resistor R40. Therefore, the reference voltage of the bandgap reference circuit will be affected by the negative temperature coefficient of the base-emitter junction of the voltage drop of transistor Q80 and can be compensated by the voltage V_{PTAT} set up across the resistor R40.

FIG. 5 shows the simulation results achieved by the circuit of FIG. 4. In particular three curves are shown, wherein the top curve shows the final temperature behaviour of the bandgap reference (i.e. V_{ref}), the second curve shows the current characteristic (I_{NL}) of the non-linear circuit 40, and the third curve shows the voltage generated by the PTAT circuitry (V_{PTAT}). It can be seen that the non-linear component indicated by the second curve only starts to have an effect at around 40° C. Also, the top curve V_{ref} shows that the bandgap reference circuit has a temperature variation of around 1.3 mV over the temperature range −40 to 120° C. compared with a 3 mV variation for a similar circuit, which does not use the non-linear compensation circuitry.

It should be appreciated that whereas the present application has been described in relation to bipolar transistors, other transistors for example FET may also be used. Also, the embodiments described herein are not intended to be limiting and the npn bipolar transistors can be replaced with pnp transistors and vice versa if the polarity of the voltage supplies are reversed. Also, although the device being compensated for is in the preferred embodiment as shown in FIG. 4 a bipolar transistor having a negative temperature coefficient across its base-emitter junction, the present invention is equally applicable to other integrated circuits that exhibit non-linear temperature characteristics. It is intended that the present invention encompass such changes and modifications as fall within the scope of the appended claims.

1. Reference generating circuitry for generating a reference signal, the circuitry comprising:
a first circuit arranged to generate a first signal having a first non-linear temperature characteristic;
a second circuit arranged to generate a second signal having a second substantially linear temperature characteristic and which partially compensates for the first signal in a first temperature range; and
a third circuit arranged to generate a third signal with a third non-linear temperature characteristic which acts to compensate for the first signal in a second temperature range.

2. Reference generating circuitry according to claim 1, wherein the reference signal is a reference voltage, and wherein each of the first, second and third signals are voltages.

3. Reference generating circuitry according to claim 2, wherein the second signal partially compensates for the first signal according to a compensation characteristic, which is modified by the third signal.

4. Reference generating circuitry according to claim 3, wherein the compensation characteristic is a bell curve, which is flattened by the third signal.

5. Reference generating circuitry for generating a reference signal, the circuitry comprising:
a first circuit arranged to generate a first signal having a first non-linear temperature characteristic;
a second circuit arranged to generate a second signal having a second substantially linear temperature characteristic and which partially compensates for the first signal according to a compensation characteristic; and
a third circuit arranged to modify the compensation characteristic of the first signal in a non-linear fashion.

6. The reference generating circuitry according to claim 5, wherein the first temperature characteristic is a negative temperature coefficient wherein the first signal of the first circuit decreases as temperature increases.

7. The reference generating circuitry according to claim 6, wherein the second temperature characteristic is a positive temperature coefficient wherein the second signal of the second circuit increases as temperature increases.

8. The reference generating circuitry of claim 2, wherein the first circuit (Q80) is a first switching device having a control terminal and first and second switching terminals.

9. The reference generating circuitry of claim 8, wherein said first switching terminal is connected to the control terminal, and the second switching terminal is connected to a first end of a first resistor (R40) having a second end which is connected to a fourth voltage (GND).

10. The reference generating circuitry of claim 9, wherein the reference voltage (V_{ref}) is generated at the first terminal of the first switching device (Q80) and is the voltage (V_{be}) across the control and second terminals of the first switching device combined with the voltage (V_{PTAT}) across the first resistor (R40).

11. The reference generating circuitry of claim 10, wherein the first terminal of the first switching device (Q80) also being connected to a first terminal of a second switching device (Q70) having a second terminal connected to a fifth voltage (VDD), the second switching device (Q70) having an input to receive an output from the second circuitry (42).

12. The reference generating circuitry of claim 11, wherein the output from the second circuitry received at the input of the second switching device is arranged to reflect a current generated from the second circuit (42) through a first branch (203) comprising said second switching device (Q70), the first switching device (Q80) and a first resistor (R40).

13. The reference generating circuitry of claim 12, wherein the second circuitry (42) is a proportional to absolute temperature (PTAT) generator comprising a second and a third branch (101, 201), each connected between the fourth (GND) and fifth voltages (VDD).

14. The reference generating circuitry of claim 13, wherein the first branch (101) comprises a third and a fourth switching device (Q30, Q40) which share a common switching terminal, and one of the switching terminals of the fourth switching device (Q40) is connected to a first end of a second resistor (R20); and wherein the second branch (201) comprises fifth and sixth switching devices (Q50, Q60) sharing a common switching terminal.

15. The reference generating circuitry of claim 14, wherein a control terminal of the third switching device (Q30) is connected to: a control terminal of the fifth switching device (Q50), the common switching terminal between the third and fourth switching devices (Q30, Q40), the control terminal of the second switching device (Q70), and the control terminal of a seventh switching device (Q10) in the third circuit (40).

16. The reference generating circuitry of claim 15, wherein a control terminal of the fourth switch device (Q40) is connected to a control terminal of the sixth switching device and the switching terminal common to both the fifth and sixth switching devices (Q50, Q60).

17. The reference generating circuitry of claim 16, wherein the other end of the second resistor (R20) is connected to both one end of a third resistor (R30) and a first switching terminal of an eight switching device (Q20), the other end of the resistor and a second switching terminal are both connected to the fourth voltage (GND).

18. The reference generating circuitry of claim 17, wherein the third circuitry comprising a fourth branch wherein a first switching terminal of the seventh switching device (Q10) is connected to the fifth voltage (VDD), and a second switching terminal is connected to a first end of a third resistor (R10), the second end is connected to the third voltage, and wherein the first end of the third resistor is connected a control terminal of the eighth switching deice (Q20).

19. The reference generating circuitry according to claim 18, wherein the switching devices are bipolar transistors.

20. A method for generating a reference signal, the method comprising:
generating a first signal having a first non-linear temperature characteristic;
generating a second signal having a second substantially non-linear temperature characteristic which acts to compensate partially for the first signal in a first temperature range; and
generating a third signal for the third non-linear characteristic which acts to compensate for the first signal in a second temperature range.

21. A method for generating a reference signal, the method comprising:
generating a first signal having a first non-linear temperature characteristic;
generating a second signal having a second substantially linear temperature characteristic which acts to compensate partially for the first signal according to a compensation characteristic; and
modifying the compensation characteristic for the first signal in a non-linear fashion.

22. A method according to claim 21, wherein the compensation characteristic is a bell curve which is flattened in the modifying step.

23. A method according to claim 22, wherein the reference signal is a reference voltage.

24. Reference generating circuitry operable to generate (i) one signal having a linear temperature characteristic that acts to compensate for a first signal in a first temperature range and (ii) another signal having a non-linear temperature characteristic that acts to compensate for said first signal in a second temperature range.

25. Reference generating circuitry according to claim 24, wherein said linear temperature characteristic of said one signal is substantially linear.

26. Reference generating circuitry according to claim 24 comprising a first circuit arranged to generate said first signal, said first signal having a first non-linear temperature characteristic.

27. Reference generating circuitry according to claim 24 further operable to generate a reference signal, said reference signal is a reference voltage, and wherein each of said first, one and another signals are voltages.

28. Reference generating circuitry according to claim 24, wherein said one signal partially compensates for the first signal according to a compensation characteristic.

29. Reference generating circuitry according to claim 28, wherein the compensation characteristic is a bell curve.
